(19) United States
(12) Patent Application Publication
(10) Pub. No.: US 2009/0302342 A1
(43) Pub. Date: Dec. 10, 2009

(54) Semiconductor Light-Emitting Device and Manufacturing Method

(76) Inventors: Ryosuke KONDO, Tokyo (JP); Mika MOCHIZUKI, Tokyo (JP)

Correspondence Address: CERMAK KENEALY VAIDYA & NAKAJIMA LLP, 515 EAST BRADDOCK RD SUITE B, Alexandria, VA, 22314, US

(21) Appl. No.: 12/480,846

(22) Filed: Jun. 9, 2009

(30) Foreign Application Priority Data
Jun. 9, 2008 (JP) 2008-150508

(51) Int. Cl. H01L 33/00; H01L 21/56

(52) U.S. Cl. 257/98; 438/26; 257/E33.059; 257/E21.502

(57) ABSTRACT

A semiconductor light-emitting device and a method for manufacturing the same can include a mixture resin encapsulating an LED chip in order to emit various colored lights, and can also include a separate transparent resin. The semiconductor light-emitting device can include a supporting plate, a base board located on the supporting plate, an upper base board located on the base board via an insulating adhesive layer, and an LED chip mounted on the supporting plate and located in a cavity composed of through-bores in the base boards. The transparent resin can be disposed circularly around an end of the insulating adhesive layer so as not to generate bubbles therein. The mixture resin can be disposed in the cavity except for that portion in which the transparent resin is located. Thus, the device can be configured to easily detect bubbles with a visual examination even if/when the bubbles are caused in the transparent resin. The disclosed device and method can prevent defective products from going to market.

This application claims the priority benefit under 35 U.S.C. §119 of Japanese Patent Application No. 2008-150508 filed on Jun. 9, 2008, which is hereby incorporated in its entirety by reference.

### BACKGROUND

1. Field

The presently disclosed subject matter relates to semiconductor light-emitting devices including an LED chip and to manufacturing methods for the same, and more particularly to reliable semiconductor light-emitting devices including a phosphor for converting a wavelength of light emitted by the LED chip, and to manufacturing methods for these devices.

2. Description of the Related Art

Semiconductor light-emitting devices that include an LED chip have been used in various fields such as vehicle lamps, general lighting, and the like in recent years. In some fields, semiconductor light-emitting devices which have high brightness are desired in order to realize an increase of light intensity. Therefore, LED chips that are used as light sources for these high brightness semiconductor light-emitting devices are also subject to a desire to increase their light intensity.

In order for LED chips to realize an increase in light intensity, an increase of light conversion efficiency thereof and an increase of driving currents for the LED chips have been devised. When the LED chips are driven by a large current, a temperature of the LED chip may increase due to self-heating. The increase of temperature may cause a performance degradation of the LED chip, such as a decrease of the light conversion efficiency, a reduction of light-emitting life, etc.

As a countermeasure, an LED chip can be mounted on a base board that has high thermal conductivity in order to prevent an increase in temperature of the LED chip due to self-heating during light-emission thereof. In some cases, a base board that includes an LED chip mounted thereon is provided with a metal radiator such as a heat sink and so on.

Meanwhile, a driving circuit is typically used to cause light to be emitted from the LED chip, and the driving circuit can be composed of a circuit board including conductor patterns and circuit parts such as resistors, diodes, connecters, etc. In the above-described semiconductor light-emitting device in which an LED chip is provided with a radiator, the above driving circuit is not generally provided because it is difficult to provide for the space thereof. Thus, the semiconductor light-emitting device with high brightness including both an LED chip and a radiator has typically lacked versatility in terms of design requirements, space requirements, etc.

A conventional light-emitting device that attempts to resolve or address the above-described problems, for example, is disclosed in Patent Document No. 1 (Japanese Patent Application Laid Open JP2007-150228). According to Patent Document No. 1, and as shown in FIG. 8, a semiconductor light-emitting device 50 includes a radiating support film 51, a base board 52, an insulating interlayer 53 and an upper board 54, which are located from a bottom so as to form a multilayer structure.

The insulating interlayer 53 is composed of an insulating layer 55 and insulating adhesive layers 56 that are located on both sides of the insulating layer 55. The upper board 54 is located on one of the insulating adhesive layers 56, which is located opposite the base board 52. The base board 52 is located on the other one of the insulating adhesive layers 56, and the radiating support film 51 is located on a bottom surface of the base board 52 opposite the insulating adhesive layers 56. The radiating support film 51 is composed of a copper foil, etc.

Each of the upper board 54 and the base board 52 is provided with conductor layers 57. Each of the conductor layers 57 is electrically insulated via the insulating interlayer 53, which is located between the upper board 54 and the base board 52. The base board 52, the insulating interlayer 53 and the upper board 54 are provided with a first through-bore 58, a second through-bore 59 and a third through-bore 60, respectively. The second and third through-bores 59, 60 are substantially the same in size, and the first through-bore 58 is formed larger than the second and third through-bores 59, 60.

The radiating support film 51 includes an LED chip 62 mounted thereon through a connecting layer 61, and the LED chip 62 is located in the first through-bore 58 of the base board 52. Each electrode of the LED chip 62 is electrically connected to each of the conductor layers 57 of the base board 52 via bonding wires 63. An encapsulating resin 67 that includes a transparent resin 64 with a phosphor 65 and transparent particles 66 mixed therein is disposed in the first, second and third through-bores 58, 59, 60. The encapsulating resin 67 encapsulates both the LED chip 62 and the bonding wires 63.

According to the above-described structure, the self-heating caused during light-emission of the LED chip 62 may be radiated by the radiating support film 51, and the increase of temperature of the LED chip 62 may be inhibited by encapsulating the LED chip 62 with the encapsulating resin 67, which includes the transparent particles 66 having high specific heat capacity such as particles of quartz glass, etc.

The driving circuit may be located on the upper base board, and may be located close to the LED chip 62. In addition, the semiconductor light-emitting device 50 may emit a different colored light from that of the LED chip 62 by encapsulating the LED chip 62 with the encapsulating resin 67 that includes transparent resin 64 mixed with the phosphor 65.

The above-referenced Patent Document is listed below, and is hereby incorporated with its English abstract in its entirety.
1. Patent Document No. 1: Japanese Patent Application Laid Open JP2007-150228

In a structure that includes a plurality of overlapped base boards like the above-described semiconductor light-emitting device 50, these semiconductor devices are frequently made by overlapping a plurality of boards via an insulating adhesive layer. In this case, the insulating adhesive layer may frequently project from between the boards. Therefore, the projecting insulating adhesive layer may cause problems such as contaminating the wire bonding area and an upward space thereof, and such as the insulating adhesive layer being dropped by (or damaged/deteriorated by) ultraviolet light through the projecting insulating adhesive layer.

Therefore, in order to prevent the insulating adhesive layer from projecting, forming each end of the insulating adhesive layers 56 that face towards the second through-bore 59 in a concave shape is one idea. FIG. 9 is an explanatory cross-section view showing an exemplary structure that is applied with the above formation in the conventional semiconductor light-emitting device of FIG. 8.

However, when the encapsulating resin 67 is disposed, the dents of the insulating adhesive layers 56 may not be filled with the encapsulating resin 67, but are sometimes formed with an air layer. The air layer may cause bubbles 70 in the encapsulating resin 67 because the air layer is pushed out by the encapsulating resin 67 when the encapsulating resin is solidified by heating and cooling. In this case, because the encapsulating resin 67 is gradually solidified, the encapsulating resin 67 may be solidified before the bubbles 70 are permitted to be exhausted outside of the encapsulating resin 67. Thus, the bubbles 70 may stay in the encapsulating resin 67 in some instances.

The bubbles 70 may cause problems such as changes in light distribution characteristics of light emitted from the LED chip 62 and/or cuts off the bonding wires 63 by contacting therewith. Therefore, it is helpful not to cause the bubbles 70 in the encapsulating resin 67 and to detect the bubbles 70 in the encapsulating resin 67 with a visual examination in order to prevent defective products from getting to market.

However, when the phosphor 65 and the transparent particles 66 are dispersed in the encapsulating resin 67, the bubbles 70 may not be detected through the encapsulating resin 67 because the phosphor 65 includes a character in which light is diffused in every direction. Consequently, the above-described structure includes a problem in that defective products may be marketed because it is sometimes difficult to detect the defective products.

The disclosed subject matter has been devised to consider the above and other problems, features, and characteristics. Thus, embodiments of the disclosed subject matter can include semiconductor light-emitting devices that can emit a light having a different wavelength from that of an LED chip, and associated manufacturing methods that do not cause and/or are designed to prevent some of the above-described problems, concerns, and characteristics related to an insulating adhesive layer. The disclosed subject matter can also include a semiconductor light-emitting device that is configured such that it is relatively easy to detect bubbles in the resin layer with a visual examination, especially when the bubbles are caused in an encapsulating resin close to the insulating adhesive layer, and thus the amount of defective products that get to market can be reduced.

### SUMMARY

The presently disclosed subject matter has been devised in view of the above and other problems, features, and characteristics. Another aspect of the disclosed subject matter includes methods of manufacture that provide reliable semiconductor light-emitting devices having broad utility and which can include a transparent resin and a mixture resin and which can provide a similar lead time while using a similar manufacture machine in comparison with conventional semiconductor light-emitting devices and processes.

According to an aspect of the disclosed subject matter, a semiconductor light-emitting device can include: a supporting plate having a chip-mounting surface; a base board including a through-bore and a top surface, located adjacent the chip-mounting surface of the supporting plate opposite the top surface thereof so as to seal one side of the through-bore with the supporting plate, and the top surface thereof provided with conductor patterns; at least one LED chip located on the chip-mounting surface of the supporting plate; and an upper base board including a through-bore and an inner surface, the upper base being located adjacent the top surface of the base board via an insulating adhesive layer having an inner end of through-bore so as to space between an inner end of the insulating adhesive layer and the inner surface thereof so that the inner end of the insulating adhesive layer cannot project from the inner surface thereof to the through-bore. The semiconductor light-emitting device can also include a transparent resin configured to be disposed on the inner surface of the upper base board and the top surface of the base board and the inner end of the insulating adhesive layer, and a mixture resin including a transparent resin and a phosphor configured to be disposed in the through-bores of the base board and the upper base board except the transparent resin so as to encapsulate the at least LED chip.

As variations of the above-described exemplary semiconductor light-emitting device, the transparent resin can also be disposed in the through-bore of the base board. In addition, the mixture resin can be configured to be disposed in the through-bore of the base board so as to encapsulate the at least LED chip, and the transparent resin can be also be configured to be disposed in the through-bore of the upper base board including the inner end of the insulating adhesive layer on the mixture resin.

In the above-described exemplary semiconductor light-emitting device, the transparent resin can be configured with a fillet geometry, and can be the same as the transparent resin that is included in the mixture resin. Each of the LED chip electrodes can be electrically connected to the chip-mounting surface of the supporting plate or the conductor patterns of the base board. In addition, the at least one LED chip can be a blue LED chip, and the phosphor that is included in the mixture resin can be a yellow phosphor.

According to the above-described exemplary semiconductor light-emitting device, the device can prevent various problems, including problems that are caused due to the projection of the insulating adhesive layer and due to bubbles caused around the inner end of the insulating adhesive layer in the encapsulating resin. When bubbles are caused in the transparent resin, the bubbles can be easily detected with a visual examination through the transparent resin, and thus the disclosed subject matter can prevent defective products from getting to market with confidence.

Another aspect of the disclosed subject matter includes methods for manufacturing the above-described semiconductor light-emitting devices. An exemplary method can include: providing a package that includes a base board including a through-bore, an upper base board including a through-bore, an insulating adhesive layer having an inner end of the through-bore disposed between the base board and the upper base board so as not to project to the through-bore of the upper base board, and a supporting plate located adjacent the base board opposite the insulating adhesive layer; mounting at least one LED chip on the supporting plate; disposing a transparent resin circularly at least on an inner end of the insulating adhesive layer; and encapsulating the at least one LED chip in the through-bores of the base board and the upper base board with a mixture resin including a transparent resin and a phosphor.

In the above-described exemplary method for manufacturing semiconductor light-emitting devices, the same or similar variations of the device can be employed as set forth in paragraph [0023].

According to the exemplary manufacturing method described above for the semiconductor light-emitting devices, the transparent resin that is disposed around the inner end of the insulating adhesive layer and the transparent resin that is included in the mixture resin can be the same resin. The transparent resin and the mixture resin can be solidified using a similar method as compared to conventional processes. Thus, the method can provide reliable semiconductor light-emitting devices using manufacturing machines that are similar to those used to manufacture conventional semiconductor light-emitting devices.

### BRIEF DESCRIPTION OF THE DRAWINGS

These and other characteristics and features of the disclosed subject matter will become clear from the following description with reference to the accompanying drawings, wherein:

FIGS. 1a to 1d are explanatory cross-section views showing an exemplary manufacturing process for a semiconductor light-emitting device made in accordance with principles of the disclosed subject matter;

FIG. 2 is a partial enlarged cross-section view depicting the semiconductor light-emitting device that is manufactured after process (d) shown in FIG. 1(d);

FIG. 3 is a partial top view depicting the semiconductor light-emitting device that is manufactured after process (d) shown in FIG. 1(d);

FIGS. 4a and 4b are explanatory cross-section views showing variations of the semiconductor light-emitting device of the first exemplary embodiment made in accordance with principles of the disclosed subject matter;

FIG. 5 is an explanatory cross-section view showing another exemplary embodiment of a semiconductor light-emitting device made in accordance with principles of the disclosed subject matter;

FIG. 6 is a partial enlarged cross-section view depicting a portion of the semiconductor light-emitting device of FIG. 5;

FIG. 7 is a top view showing the semiconductor light-emitting device of FIG. 5;

FIG. 8 is an explanatory cross-section view showing a conventional semiconductor light-emitting device; and

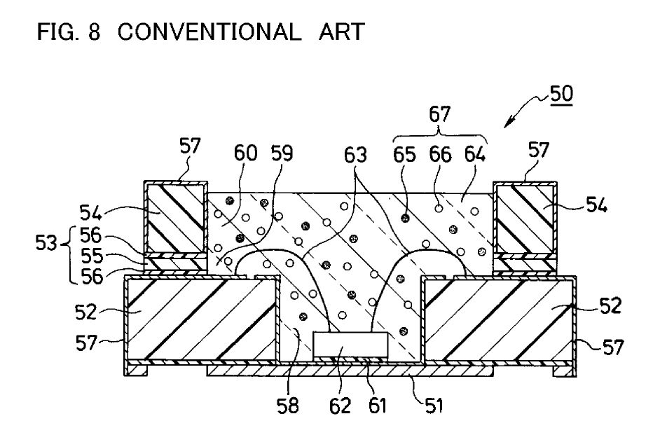

FIG. 9 is an explanatory cross-section view depicting a technique of solutions in the disclosed subject matter.

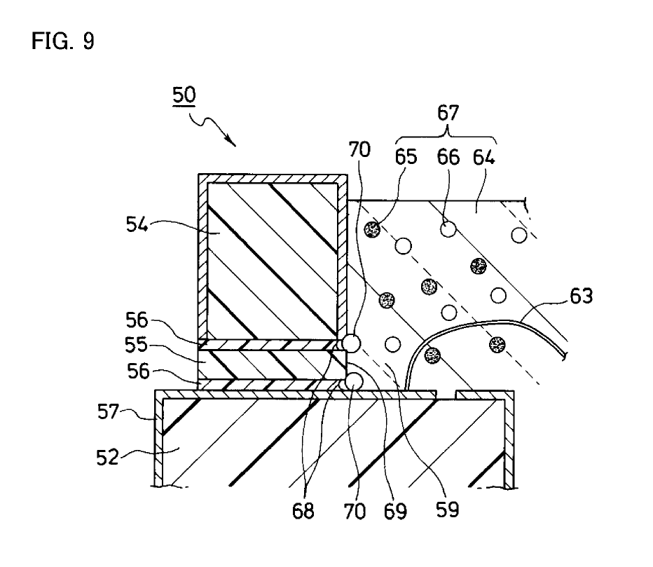

### DETAILED DESCRIPTION OF EXEMPLARY EMBODIMENTS

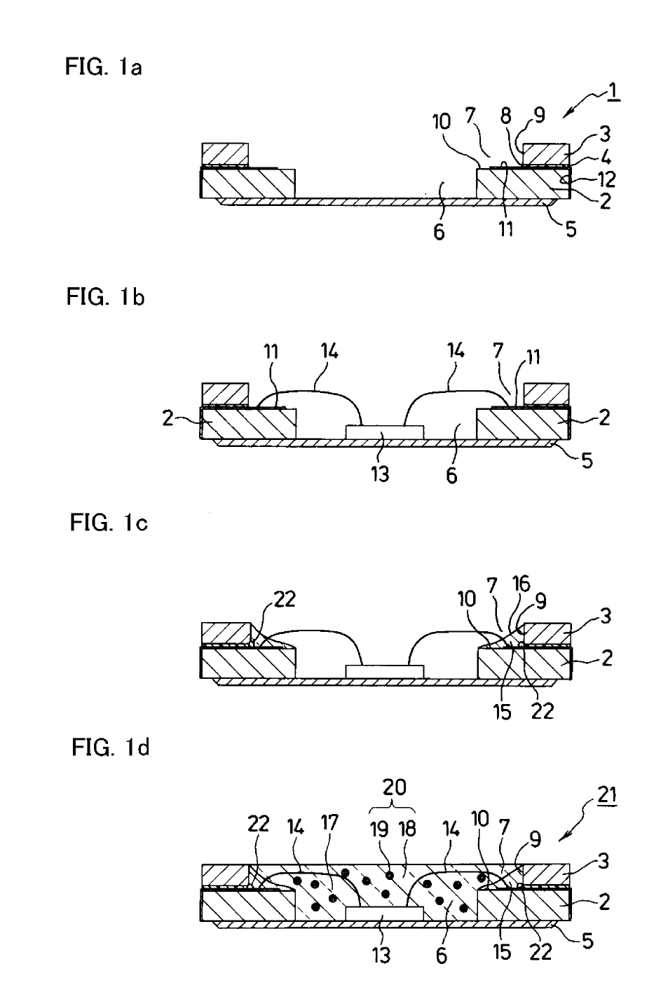

Exemplary embodiments of the disclosed subject matter will now be described in detail with reference to FIGS. 1 to 7. The disclosed subject matter can provide reliable semiconductor light-emitting devices including an LED chip. The semiconductor light-emitting devices can emit a different wavelength from that of the LED chip, and can do so, for example, by including an encapsulating resin including a phosphor. The structure can be composed of a plurality of base boards and an insulating adhesive layer. However, the structure can be configured such that it is essentially difficult to cause bubbles in the encapsulating resin except at a position close to the insulating adhesive layer.

If/when the bubbles are caused in the encapsulating resin close to the insulating adhesive layer, the structure can prevent defective products that include such bubbles from getting to the market with confidence because the bubbles can be easily detected with a visual examination. Thus, the disclosed subject matter can provide reliable semiconductor light-emitting devices that can emit various colored lights, and can provide the manufacturing method for these devices.

FIGS. 1a to 1d are explanatory cross-section views showing a manufacturing process for a semiconductor light-emitting device of a first exemplary embodiment in accordance with principles of the disclosed subject matter. In process (a) shown in FIG. 1a, the method can include providing a package 1 for mounting an LED chip. The package 1 can include: a base board 2 that is composed of an insulating material; an upper base board 3 composed of an insulating material that is disposed on the base board 2 via an insulating adhesive layer 4; and a supporting plate 5 having a chip-mounting surface composed of a metallic material that is disposed on a bottom surface of the base board 2 opposite the upper base board 3.

The base board 2 and the upper base board 3 can be provided with through-bores 6, 7, respectively. The through-bore 7 of the upper base board 3 can be larger than the through-bore 6 of the base board 2. An end of the insulating adhesive layer 4 faces towards an inner surface 9 of the through-bore 7 and can be formed in a concave shape. Conductor patterns 11 can be located on a top surface 10 of the base board 2 that is located opposite the supporting plate 5, and can extend to the bottom surface of the base board 2 along an outside surface thereof. The supporting plate 5 is disposed on the bottom surface of the base board 2 so as to seal the through-bore 6 of the base board 2 with the chip-mounting surface that can be defined by a whole top surface of the supporting plate 5.

In the first exemplary embodiment, the base board 2 and the upper base board 3 can be formed from a glass epoxy board. The insulating adhesive layer 4 can include a prepreg material, which can include an uncured epoxy resin in a glass fiber. The insulating adhesive layer 4 can be disposed on the base board 2 so that the end 8 thereof can be spaced approximately 0.1 mil meters from the inner surface 9 of the through-bore 7 of the upper base board 3 in an opposite direction of the inner surface 9. Thus, the problem in conventional devices in which an insulating adhesive layer may project into the through-bore 7 can be prevented.

In process (b) shown in FIG. 1b, the method can include mounting an LED chip 13 on the supporting plate 5 that is located at a bottom of the both through-bores 6,7. In this case, the LED chip 13 can be mounted on the chip-mounting surface of the supporting plate 5 via a conductive material such as a silver paint. Each of the electrodes of the LED chip 13 can be electrically connected to respective conductor patterns 11 via bonding wires 14.

In addition, a driving circuit for the LED chip 13 may be located on a space of the top surface 10 that is not covered by the upper base board 3, and may be constructed using the conductive patterns 11. The conductor patterns 11 can also be used for receiving a power supply from the outside. Furthermore, the heat generated from the LED chip 13 can be effectively radiated from the supporting plate 5 to the outside.

In process (c) shown by FIG. 1c, the method can include covering the end 8 of the insulating adhesive layer 4 with a transparent resin 15 and solidifying the transparent resin 15. In this case, the transparent resin 15 can cover from the inner surface 9 of the through-bore 7 to the top surface 10 including the conductor patterns 11 of the base board 2 while covering the end 8 of the insulating adhesive layer 4. The transparent resin 15 can be solidified by heating and cooling. The solidified transparent resin 15 can be formed as a resin fillet 16 so as to cover both the inner surface 9 of the through-bore 7 and the top surface 10 of the base board 2 while wrapping the end 8 of the insulating adhesive layer 4.

The transparent resin 15 should not include a phosphor, a diffuser and the like therein, and a one-component resin can be used as the transparent resin 15. In this case, it can become difficult to cause bubbles in the transparent resin 15 because the uncured transparent resin 15 can be easily spread around the end 8 of the insulating adhesive layer 4 with a small quantity while adhering around the end 8, and can be prompt to solidify when an uncured transparent resin 15 is a one-component resin.

In process (d) shown in FIG. 1d, the method can include disposing a mixture resin 20 in a cavity 17 that is formed by the supporting plate 5 and both through-bores 6, 7, (and transparent resin 15), and solidifying the mixture resin 20 by heating and cooling. In this case, the mixture resin 20 can be disposed in the cavity 17 before the transparent resin 15 is solidified, and the mixture resin 20 and the transparent resin 15 can be solidified together. Thus, the LED chip 13 and bonding wires 14 can be encapsulated with the mixture resin 20 that is used as an encapsulating resin, and the semiconductor light-emitting device 21 can be manufactured.

The mixture resin 20 can include a transparent resin 18 with a phosphor 19, a diffuser, and the like, and can convert a wavelength of light emitted from the LED chip 13 into a different wavelength. The transparent resin 18 of the mixture resin 20 can be the same as the transparent resin 15 that circularly covers an area from the inner surface 9 of the through-bore 7 to the top surface 10 of the base board 2 in order to avoid peeling between boundary surfaces thereof.

For instance, an epoxy resin, a silicon resin and the like can be used for the transparent resins 15, 18. When the transparent resin 18 and the transparent resin 15 are the same transparent resin, the transparent resin 18 in place of the resin 15 can be disposed in process (c), and the mixture resin 20 composed of the transparent resin 18 can be disposed in process (d). Thus, the use of the same transparent resin can result in easier handling with regard to the handling of resins in the processes (c) and (d).

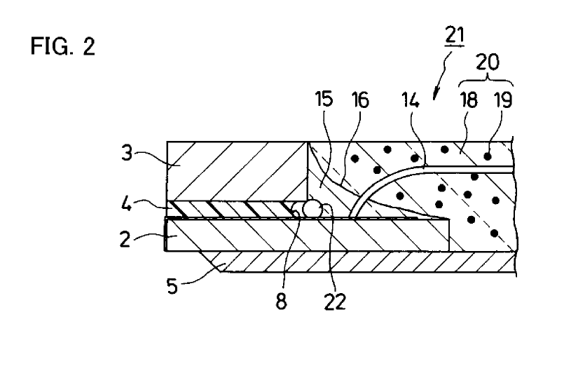

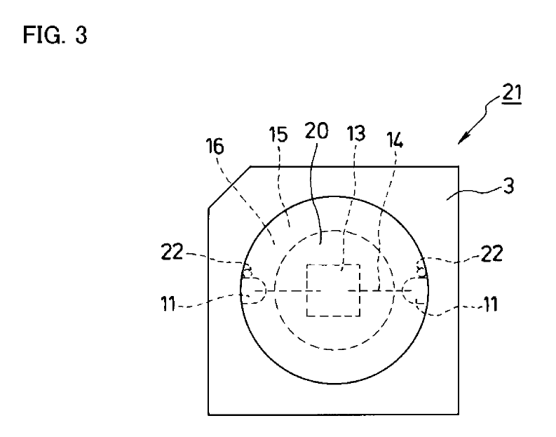

FIG. 2 is a partial enlarged cross-section view depicting the semiconductor light-emitting device 21 that is manufactured after the process (d) shown in FIG. 1(d). When bubbles happen for any possible reason, it is highly possible that the bubble(s) 22 occur close to the end 8 of the insulating adhesive layer 4. FIG. 3 is a partial top view depicting the semiconductor light-emitting device 21. The resin fillet 16 that is made of the transparent resin 15 can be located on the site of possible bubbles 22. Thus, when the semiconductor light-emitting device 21 is viewed from a top thereof, the bubbles 22 can be easily recognized through the resin fillet 16 as shown in FIG. 22.

Thus, because the bubbles 22 can be detected with a visual examination with confidence, the disclosed subject matter can prevent defective products from getting to market by clearing the defective products from good manufacturing products when the bubbles 22 are caused in the transparent resin 15. In the first exemplary embodiment, the transparent resin 18 of the mixture resin 20 is disposed along with the phosphor 19 in the cavity 17 (excluding the transparent resin 15), and can be used as the encapsulating resin for encapsulating the LED chip 13.

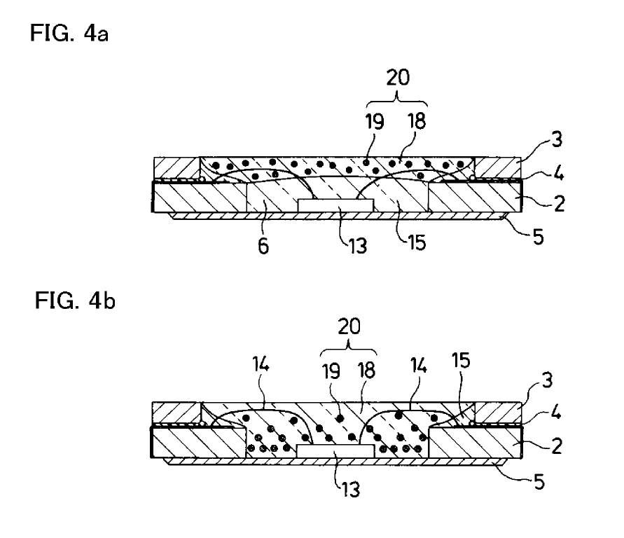

However, the location of the transparent resin 18 is not limited to the above location, but can be changed according to usage desires of the semiconductor light-emitting device 21. FIG. 4a is an explanatory view showing a variation of the semiconductor light-emitting device 21. The above-described transparent resin 15 can also be disposed in the through-bore 6, and the mixture resin 20 including the phosphor 19 can be disposed on the transparent resin 15.

In this case, because the transparent resin 15 can be dropped in the though-bore 6 from the top surface 10 of the base board 2, it become easy to form the resin fillet 16 in process (c). In addition, the mixture resin 20 including the phosphor 19 can be formed relatively thin and uniform. Therefore, it may be easy to control the light distribution of the semiconductor light-emitting device 21. In a slight variation of the device shown in FIG. 4a, the amount of transparent resin 15 can be increased to fill slightly over the lip of the through bore 6 such that the transparent resin 15 covers the top exposed surface of the base board 2 including the circuit pattern 11 as well as the ends of the insulating adhesive layer 4. In this manner, the transparent resin 15 can also cover the ends 8 of the insulating adhesive layer 4 and provide clear view of any bubble(s) 22 that may form therein during manufacture. FIG. 4b is an explanatory view showing another variation of the semiconductor light-emitting device 21.

A specific gravity of the phosphor 19 that is dispersed into the mixture resin 20 can be higher than that of the transparent resin 18 that composes the mixture resin 20. Therefore, the distributed concentration of phosphor 19 can become gradually higher in a downward direction as shown in the figures due to the fact that the phosphor 19 precipitates downwards because the transparent resin 18 has a low specific gravity when in the state of hot liquid resin before being solidified. The above-described bubbles 22 can become easier to detect in this structure, because the phosphor 19 may not be particularly located over the bubbles 22. Thus, the structure of FIG. 4b can prevent defective products from getting to market with more confidence.

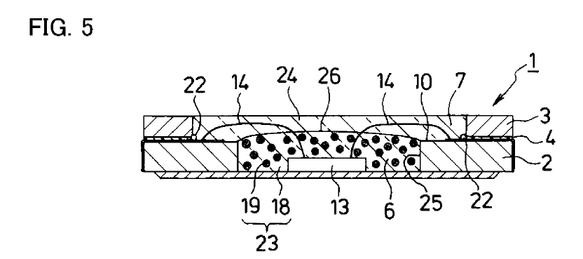

Another embodiment will now be given with reference to FIG. 5. FIG. 5 is an explanatory cross-section view showing an exemplary semiconductor light-emitting device made in accordance with principles of the disclosed subject matter. In this exemplary embodiment of the disclosed subject matter, the structure of the package 1 can be the same as that in the exemplary embodiment of FIG. 1.

The package 1 can include the base board 2 having the through-bore 6; the upper base board 3 having the through-bore 7; the insulating adhesive layer 4 for attaching the upper base board 3 to the base board 2; and the supporting plate 5 having a chip-mounting surface. A difference between the embodiments can be the structure and/or composition of the resins disposed in the cavity 17.

More specifically, a first encapsulating resin 23 that includes a transparent resin 18 with phosphor 19 can be disposed in the through-bore 6 of the base board 2. A second encapsulating resin 24 that is composed of a transparent resin not including the phosphor can be disposed in the through-bore 7 of the upper base board that is located on the first encapsulating resin 23.

In this case, the first encapsulating resin 23 can cover the entire LED chip 13, however, the first encapsulating resin 23 may not cover the top surface 10 of the base board 2. In this case, although the first encapsulating resin 23 may include an expanded middle portion 26 thereof in the through-bore 7 of the upper base board 3 from an inner surface 25 of the base board 2 (formed due to surface tension, for example), the expansion of the encapsulating resin 23 may not cause a problem.

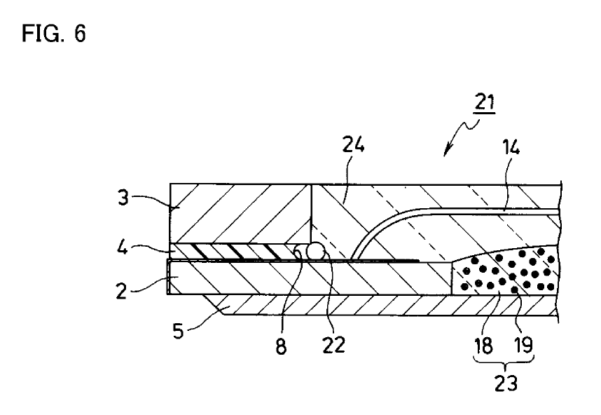

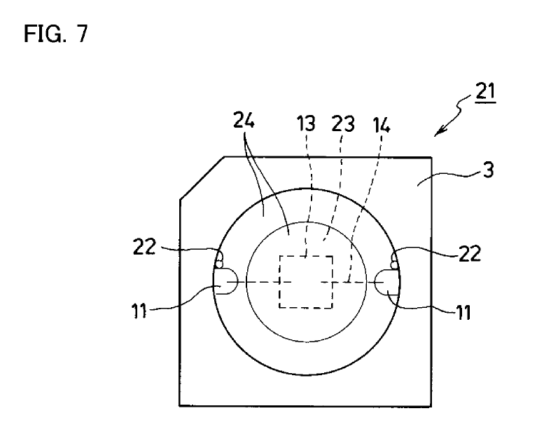

FIG. 6 is a partial enlarged cross-section view depicting a portion of the semiconductor light-emitting device 21 of FIG. 5. In this exemplary embodiment, if/when the bubbles 22 are caused, the second encapsulating resin 24 composed of transparent resin can be located on the bubbles 22, which may be located close to the end 8 of the insulating adhesive layer 4. FIG. 7 is a top view showing the semiconductor light-emitting device 21.

Thus, when the bubbles 22 are caused for any possible reason, the bubbles 22 can be easily detected with a visual examination through the transparent second encapsulating resin 24 from the top of the semiconductor light-emitting device 21 as shown in FIG. 7. This exemplary embodiment of the disclosed subject matter can also prevent defective products from getting to market by allowing the manufacturer to easily clear defective products from good products.

The transparent second encapsulating resin 24 disposed in the through-bore 7 of the upper base board 3 can be the same as the transparent resin 18 that is included in the first encapsulating resin 23 disposed in the through-bore 6 of the base board 2 so as to prevent peeling between boundary surfaces thereof. For instance, an epoxy resin, a silicon resin and the like can be used for the transparent resins 24, 18.

In the above-described exemplary embodiments, the insulating adhesive layer 4 can include a prepreg material that includes an uncured epoxy resin in a glass fiber. However, an adhesive sheet that is composed of an epoxy resin and the like, a multilayer that provides both sides of glass epoxy board with adhesive sheets, and the like can be used in place of the prepreg material for the insulating adhesive layer 4 according to the desired usage and the specification of the semiconductor light-emitting device 21. In this case, the layer that is spaced from the inner surface 9 of the through-bore 7 can become a part layer in the sheet that may project, and also can become the whole sheet.

A description of light wavelength conversion using the LED chip 13 and the phosphor 19 will now be given. For example, when the semiconductor light-emitting device 21 emits white light, the LED chip 13 can be a blue LED chip that emits a blue light with a peak wavelength of 450 nm, and the phosphor 19 can be a yellow phosphor such as YAG:Ce, (Ca, Sr, Ba)₂SiO₄:Eu and the like for converting blue light to a complementary yellow light. A part of the blue light emitted from the blue LED chip 13 excites the phosphor 19 and converts it to yellow light, which can be mixed with other parts of the blue light emitted from the blue LED chip 13 by means of additive color mixture. Thus, the semiconductor light-emitting device 21 can emit light having an approximately white color tone.

The semiconductor light-emitting device 21 can also emit light of approximately white color tone through a green phosphor 19 (e.g. SrGa₂S₄:Eu) and a red phosphor 19 (e.g. SrS:Eu) for converting blue light to green light and/or red light. A part of the blue light emitted from the blue LED chip 13 excites the two phosphors 19 and converts the light to green light and/or red light, which can be added to or mixed with other parts of the blue light emitted from the blue LED chip 13 to generate an approximately white light by means of additive color mixture.

When the above LED chip 13 emits ultraviolet light (ultraviolet LED chip), the semiconductor optical device 21 can also emit light of approximately white color tone through the use of three kinds of phosphors 19 for converting ultraviolet light to blue light, green light and red light. The ultraviolet light emitted from ultraviolet LED chip 13 excites the three phosphors 19 and converts the light to blue light, green light and red light, which can be added together to generate approximately white light by means of additive color mixture.

Furthermore, when the wavelength of light emitted from the LED chip 13 and the phosphor 19 (or wavelength conversion material) are appropriately selected and combined, light of various color tone other than white light can be generated. When the LED chips 13 are composed of a plurality of light-emitting chips of different light-emitting colors, light of various color tone other than the light-emitting color of the light-emitting chips can be generated through the encapsulating resin that is mixed with phosphor 19.

As described above, the disclosed subject matter can provide a reliable semiconductor light-emitting device that can emit light having a different wavelength from that of the LED chip in the device. The semiconductor light-emitting device can be configured to include a plurality of overlapping base boards having a through-bore and an insulating adhesive layer so as to create a space between an end of the insulating adhesive layer and an inner surface of the through-bore in an opposite direction of the inner surface. A transparent resin can be located on surfaces, including the end of the insulating adhesive layer, and a mixture resin can be disposed in the through-bores in which the LED chips are mounted therein.

Thus, various problems and characteristics can be avoided, such as the insulating adhesive layer projecting towards the through-bore and creation of bubbles close to the end of the insulating adhesive film. If/When the bubbles are caused in the transparent resin, because the bubbles can be easily detected with a visual examination through the transparent resin, the disclosed subject matter can further prevent defective products from making it to market with confidence.

In addition, the heat generated from the LED chip can be effectively radiated from the supporting plate to which it is mounted, and the driving circuit can also be located on the base boards. Thus, the disclosed subject matter can provide reliable semiconductor light-emitting devices having broad utility and high brightness that can emit various colored lights.

While there has been described what are at present considered to be exemplary embodiments of the invention, it will be understood that various modifications may be made thereto, and it is intended that the appended claims cover such modifications as fall within the true spirit and scope of the invention. All conventional art references described above are herein incorporated in their entirety by reference.

What is claimed is:

1. A semiconductor light-emitting device comprising:
a supporting plate having a chip-mounting surface;
a base board including a first through-bore and a top surface, the base board located adjacent the chip-mounting surface of the supporting plate, the top surface of the base board located opposite the supporting plate so as to seal one side of the first through-bore with the supporting plate, and the top surface of the base board including at least one conductor pattern;
at least one LED chip including LED chip electrodes, the LED chip connected to the chip-mounting surface of the supporting plate;
an upper base board including an inner surface and a second through-bore that is larger than the first through-bore of the base board;
an insulating adhesive layer including a third through-bore and an inner end, the third through-bore located between the second through-bore and the top surface of the base board, the inner end of the insulating adhesive layer being spaced from the inner surface, and the inner end being located between the base board and the upper base board so as not to project from the inner surface to the second through-bore;
a primary transparent resin disposed adjacent the inner surface of the upper base board, the top surface of the base board, and the inner end of the insulating adhesive layer; and
a mixture resin including a secondary transparent resin and a phosphor, the mixture resin disposed in the first, second, and third through-bores and adjacent the primary transparent resin so as to encapsulate the at least one LED chip.

2. A semiconductor light-emitting device comprising:
a supporting plate having a chip-mounting surface;
a base board including a first through-bore and a top surface, the base board located adjacent the chip-mounting surface of the supporting plate, the top surface of the base board located opposite the supporting plate so as to seal one side of the first through-bore with the supporting plate, and the top surface of the base board including at least one conductor pattern;
at least one LED chip including LED chip electrodes, the at least one LED chip connected to the chip-mounting surface of the supporting plate;
an upper base board including an inner surface and a second through-bore that is larger than the first through-bore of the base board;
an insulating adhesive layer including a third through-bore and an inner end, the third through-bore located between the second through-bore and the top surface of the base board, the inner end of the insulating adhesive layer being spaced from the inner surface, and the inner end of the insulating adhesive layer being located between the base board and the upper base board so as not to project from the inner surface to the second through-bore;
a mixture resin including a secondary transparent resin and a phosphor, the mixture resin disposed in the first through-bore of the base board so as to encapsulate the at least one LED chip; and
a primary transparent resin disposed in the second through-bore of the upper base board and the third through-bore, and adjacent the inner end of the insulating adhesive layer and the mixture resin.

3. The semiconductor light-emitting device according to claim 1, wherein the primary transparent resin is also disposed in the first through-bore of the base board.

4. The semiconductor light-emitting device according to claim 1, wherein the primary transparent resin is configured with a fillet geometry.

5. The semiconductor light-emitting device according to claim 2, wherein the primary transparent resin is configured with a fillet geometry.

6. The semiconductor light-emitting device according to claim 3, wherein the primary transparent resin is configured with a fillet geometry.

7. The semiconductor light-emitting device according to claim 1, wherein the primary transparent resin and the secondary transparent resin are the same resin.

8. The semiconductor light-emitting device according to claim 2, wherein the primary transparent resin and the secondary transparent resin are the same resin.

9. The semiconductor light-emitting device according to claim 3, wherein the primary transparent resin and the secondary transparent resin are the same resin.

10. The semiconductor light-emitting device according to claim 4, wherein the primary transparent resin and the secondary transparent resin are the same resin.

11. The semiconductor light-emitting device according to claim 5, wherein the primary transparent resin and the secondary transparent resin are the same resin.

12. The semiconductor light-emitting device according to claim 6, wherein the primary transparent resin and the secondary transparent resin are the same resin.

13. The semiconductor light-emitting device according to claim 1, wherein each of the LED chip electrodes is electrically connected to at least one of the chip-mounting surface of the supporting plate and the at least one conductor pattern of the base board.

14. The semiconductor light-emitting device according to claim 2, wherein each of the LED chip electrodes is electrically connected to at least one of the chip-mounting surface of the supporting plate and the at least one conductor pattern of the base board.

15. The semiconductor light-emitting device according to claim 3, wherein each of the LED chip electrodes is electrically connected to at least one of the chip-mounting surface of the supporting plate and the at least one conductor pattern of the base board.

16. The semiconductor light-emitting device according to claim 1, wherein the at least one LED chip is a blue LED chip, and the phosphor included in the mixture resin is a yellow phosphor.

17. The semiconductor light-emitting device according to claim 2, wherein the at least one LED chip is a blue LED chip, and the phosphor included in the mixture resin is a yellow phosphor.

18. A method for manufacturing a semiconductor light-emitting device comprising:
providing a package that includes a base board including a first through-bore, an upper base board including a second through-bore, an insulating adhesive layer including a third through-bore disposed between the base board and the upper base board so as not to project to the first and second through-bores, and a supporting plate located adjacent the base board opposite the insulating adhesive layer;
mounting at least one LED chip on the supporting plate;
disposing a transparent resin circularly at least in the third through-bore of the insulating adhesive layer; and
encapsulating the at least one LED chip in the first, second and third through-bores with a mixture resin including a transparent resin and a phosphor.

19. The method for manufacturing a semiconductor light-emitting device according to claim 18, wherein the transparent resin that is disposed at least on the third through-bore of the insulating adhesive layer and the transparent resin that is included in the mixture resin are the same one-component resin.

20. The method for manufacturing a semiconductor light-emitting device according to claim 19, wherein the supporting plate includes a chip mounting surface, the base board includes at least one conductor pattern, and the at least one LED chip includes a plurality of LED chip electrodes, and each of the LED chip electrodes is electrically connected to at least one of the chip-mounting surface of the supporting plate and the at least one conductor pattern of the base board.
